(19) United States
(12) Patent Application Publication
(10) Pub. No.: US 2024/0254623 A1
(43) Pub. Date: Aug. 1, 2024

(54) VAPOR SUPPLY APPARATUS

(71) Applicant: SAMSUNG ELECTRONICS CO., LTD., Suwon-si (KR)

(72) Inventors: Changhwan Kim, Suwon-si (KR); Takafumi Noguchi, Yokohama-shi (JP); Toshihiro Iizuka, Yokohama-shi (JP); Kenichi Nagayama, Yokohama-shi (JP)

(21) Appl. No.: 18/421,553

(22) Filed: Jan. 24, 2024

(30) Foreign Application Priority Data
Jan. 30, 2023 (JP) 2023-011892
Nov. 3, 2023 (KR) 10-2023-0150490

(51) Int. Cl. C23C 16/448; C23C 16/455

(52) U.S. Cl. CPC C23C 16/448; C23C 16/45557; C23C 16/45561

(57) ABSTRACT

A vapor supply apparatus is described. The apparatus stably supplies vapor to a process chamber when the vapor pressure of the material is lower than the process pressure. The apparatus includes a supply container accommodating a solid or a liquid having a vapor pressure which is lower than the process pressure. The vapor may be generated in the supply container from a liquid or from a solid. A buffer tank is interposed between the supply container and the process chamber and into which the vapor from the container is introduced by reducing pressure. The apparatus includes a mechanism for pressurizing the buffer tank and pressure-feeding the vapor to the process chamber.

### CROSS-REFERENCE TO RELATED APPLICATION(S)

This application claims benefit of priority to Korean Patent Application No. 10-2023-0150490 filed on Nov. 3, 2023, in the Korean Intellectual Property Office and to Japanese Patent Application No. 2023-011892 filed on Jan. 30, 2023, in the Japan Patent Office, the disclosures of which are incorporated herein by reference in their entireties.

### BACKGROUND

Vapor supply apparatuses have been used to perform film etching and film formation, such as atomic layer deposition (ALD), atomic layer epitaxy (ALE), and chemical vapor deposition (CVD). Recently, raw materials with high atomic numbers, such as rare-earth elements, have been used for film formation and etching. Using such materials has made it difficult to stably supply vapor because the vapor pressures of many raw materials are lower than the process pressure of a process chamber.

### SUMMARY

In general, in some aspects, the present disclosure is directed to a vapor supply apparatus, which is used for both sublimation and evaporation, and is capable of pressurizing a buffer tank to a desired pressure.

The vapor supply apparatus includes a container accommodating a solid or liquid having a vapor pressure lower than a process pressure of a process chamber in which a process is performed using vapor. The container generates the vapor from a liquid in which the solid is sublimed or the liquid is evaporated. A buffer tank is interposed between the container and the process chamber and into which the vapor generated in the container is introduced by reducing pressure. The buffer tank includes a pressure-feeding mechanism to pressurize the buffer tank and to-feed the appropriately pressurized vapor to the process chamber. With the above configuration, the vapor supply device may be used for either sublimation or evaporation and in which the buffer tank is pressurized.

The pressure-feeding mechanism may be a cylinder or an accumulator. With the above-described configuration, the buffer tank may be improved and pressurized.

The pressure-feeding mechanism may be an inert gas introducing mechanism. With the above configuration, the buffer tank may be pressurized with an inert gas.

The vapor supply system may include a controller for controlling a flow rate or a pressure to control the concentration of the vapor when it is introduced into the process chamber or when it is transferred from a container to a buffer tank.

The vapor supply apparatus may further include a first pipe connecting the buffer tank to the container and a second pipe connecting the buffer tank to the process chamber, wherein the container, the buffer tank, the first pipe, and the second pipe, respectively, each have a heating mechanism, and the heating mechanisms each are independently controlled regarding temperature. With the above configuration, vapor may not condense in the container, the buffer tank, the first pipe, and the second pipe and return to liquid.

The container and the buffer tank may, respectively, each have a pressure gauge, and the pressure of the container and the pressure of the buffer tank may be independently controlled as the pressure gauges respectively monitor a saturated vapor pressure. With the above configuration, the maximum amount of raw material may be pressure-fed into the process chamber using the saturated vapor pressure.

The number of buffer tank is two or more. With the above configuration, processing may be performed continuously in the process chamber.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a diagram illustrating an example of a vapor supply apparatus and a first operation of a vapor pressure-feeding process;

FIG. 2 is a diagram illustrating a second operation of a vapor pressure-feeding process;

FIG. 3 is a diagram illustrating a third operation of a vapor pressure-feeding process;

FIG. 4 is a diagram illustrating a fourth operation of a vapor pressure-feeding process;

FIG. 5 is a diagram illustrating an example of a system of pressure-feeding vapor from a buffer tank;

FIG. 6 is a diagram illustrating a first configuration of an example of a vapor supply apparatus according to the related art; and

FIG. 7 is a diagram illustrating a second configuration of an example of a vapor supply apparatus according to the related art.

### DETAILED DESCRIPTION

Hereinafter, example implementations will be described with reference to the drawings. However, the present disclosure is not limited to the following example implementations. In addition, not all of the components described in the example implementations are essential as a means to solve the problems. For clarity of explanation, the following description and drawings are simplified or omitted. In each drawing, like elements are given like reference numerals, and redundant descriptions are omitted as necessary.

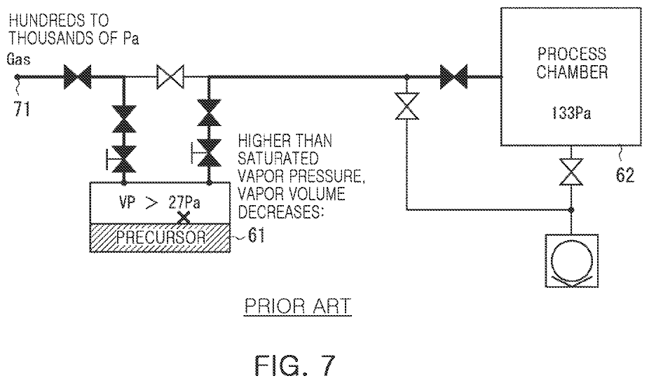

FIG. 6 is a diagram illustrating a first configuration of a vapor supply apparatus according to the related art. FIG. 7 is a diagram illustrating a second configuration of a vapor supply apparatus according to the related art.

Y(i-PrCp)₃ is a substance having a melting point of 70° C., a boiling point of 180° C., and a saturated vapor pressure of 0.2 Torr (about 27 Pa). As shown in FIGS. 6 and 7, it is considered to introduce a precursor of this substance into a container 61 to be introduced into a process chamber 62. As shown in FIG. 6, even if a valve from the container 61 to the process chamber 62 is opened, since a process pressure of the process chamber 62 is 133 Pa, which is greater than a saturated vapor pressure of 27 Pa, and thus the raw material is not pressure-fed.

As shown in FIG. 7, when vapor is pressure-fed by introducing hundreds to thousands of Pa of inert gas from a gas source 71, since the pressure of the container 61 becomes higher than the saturated vapor pressure and the amount of vapor decreases, vapor is not continuously pressure-fed to the process chamber 62.

The present disclosure provides a vapor supply apparatus for stably supplying vapor having a saturated vapor pressure lower than a process pressure of a process chamber.

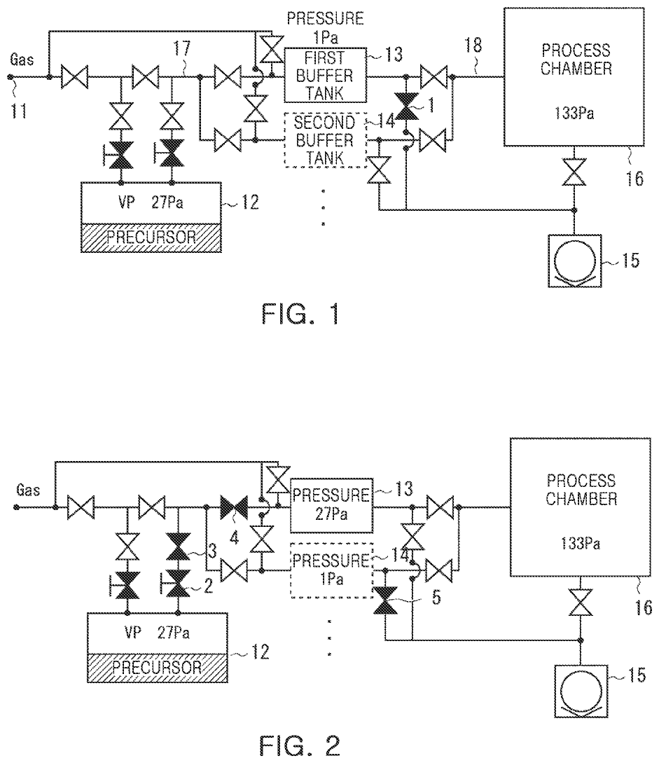

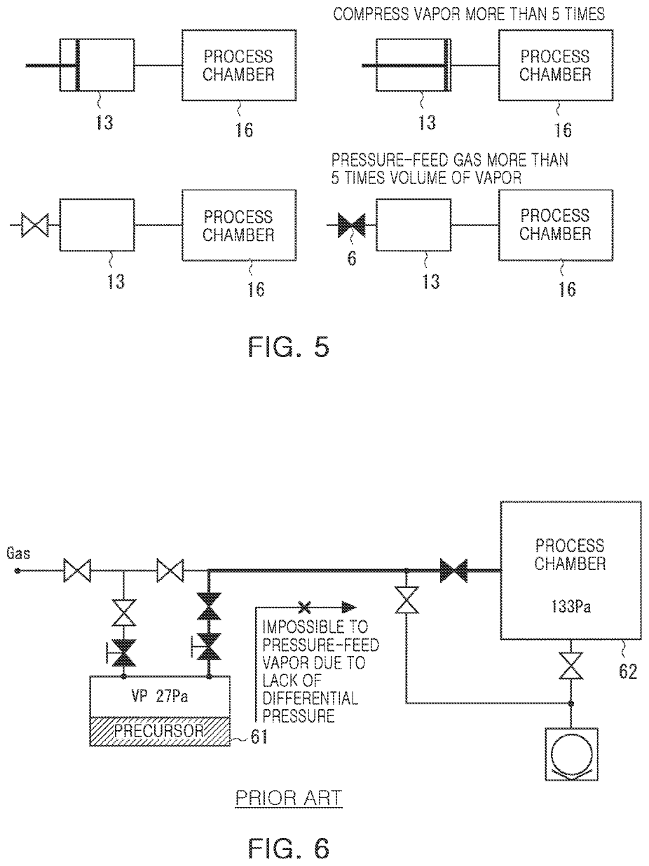

FIG. 1 is a diagram illustrating a configuration of a vapor supply apparatus and a first operation of the vapor pressure-feeding process. FIG. 5 is a diagram illustrating a configuration of a system for pressure-feeding vapor from a buffer tank. Referring to FIGS. 1 and 5, the vapor supply apparatus will be described.

As shown in FIG. 1, the vapor supply apparatus may include a container 12, a buffer tank 13 (or a first buffer tank), and a pressure-feeding mechanism for pressure-feeding vapor.

The container 12 may accommodate a solid or liquid having a vapor pressure lower than a process pressure of the process chamber 16 in which a process is performed using vapor. The container 12 may generate vapor from a liquid precursor or from a solid precursor. The container 12 may be connected to the process chamber 16 via the buffer tank 13 to transfer vapor. The container 12 may accommodate a solid, melt the solid into a liquid by heating, and evaporate the liquid to generate vapor. In addition, the container 12 may accommodate a liquid and evaporate the liquid by heating to generate vapor. In addition, the container 12 may accommodate a solid and sublimate the solid by heating to generate vapor.

A container for generating vapor by evaporation from a liquid and a container for generating vapor by sublimation from a solid have completely different structures, but the container of the vapor supply apparatus of the present disclosure may be either type of container.

The process chamber 16 may perform a film formation process, such as ALD, ALE, and CVD, a deposition process, etc. In the process chamber 16, a process may be performed under a reduced pressure, and any process may be performed therein.

The buffer tank 13 may be interposed between the container 12 and the process chamber 16, and vapor generated in the container 12 may be introduced by reducing the pressure. The buffer tank 13 may temporarily collect vapor, which is a raw material. Two or more buffer tanks may be provided: a first buffer tank 13 plus a second buffer tank 14. By providing two or more buffer tanks (e.g., first buffer tank 13 and second buffer tank 14), processes may be performed continuously in the process chamber.

As shown in FIG. 5, the pressure-feeding mechanism for pressure-feeding vapor may include a cylinder or an accumulator provided in the buffer tank 13 or may include an inert gas introduction mechanism using a gas source 11. The cylinder or accumulator provided in the buffer tank 13 may reduce the volume in the buffer tank 13 and pressure-feed vapor into the process chamber 16. The cylinder or accumulator may compress the vapor volume by more than 5 times.

In addition, when a valve 6 between the gas source 11 and the buffer tank 13 is opened, the inert gas may flow from the gas source 11 to press the buffer tank 13 to pressure-feed vapor to the process chamber 16. The gas source 11 may pressure-feed gas at 5 times or more than the vapor saturation pressure.

By compressing vapor 5 times or more gas having a saturated vapor pressure of 0.2 Torr may be transferred to the process chamber having a process pressure of 1 Torr. Pressure-feeding vapor as a gas of more than 5 times the volume of the vapor may also have the same effect.

Although not shown, the buffer tank 13 and the container 12 may each include a heating mechanism. In addition, a first pipe 17 connecting the buffer tank 13 to the container 12 may include a heating mechanism. In addition, a second pipe 18 connecting the buffer tank 13 to the process chamber 16 may include a heating mechanism. These heating mechanisms may be independently controlled regarding temperature. Accordingly, it is possible to prevent vapor from condensing in the container 12, the buffer tank 13, the first pipe 17, and the second pipe 18 and returning to a liquid form or to a solid form.

Although not shown, the container 12 and the buffer tank 13 may each include a pressure gauge and a controller. Each pressure gauge may measure and monitor the saturated vapor pressure of the raw material, so that the pressures of the container 12 and the buffer tank 13 may be controlled independently by the controllers. Accordingly, the maximum amount of raw material may be pressure-fed into the process chamber using the saturated vapor pressure.

By using such a vapor supply apparatus, vapor having the saturated vapor pressure lower than the process pressure of the process chamber may be stably supplied.

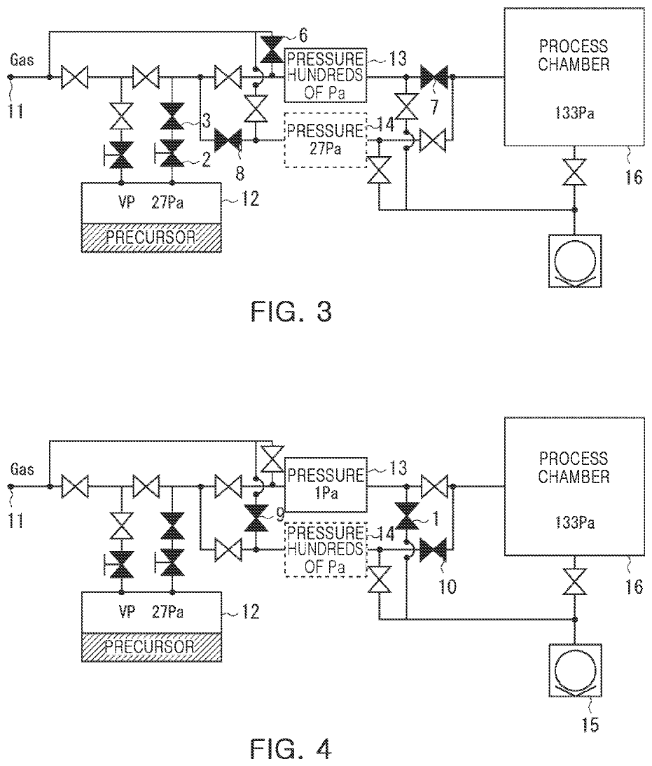

FIG. 1 is a diagram illustrating a configuration of a vapor supply apparatus and a first operation of a vapor pressure-feeding process. FIG. 2 is a diagram illustrating a second operation of the vapor pressure-feeding process. FIG. 3 is a diagram illustrating a third operation of the vapor pressure-feeding process. FIG. 4 is a diagram illustrating a fourth operation of the vapor pressure-feeding process. The vapor pressure-feeding process is described with reference to FIGS. 1 to 4.

As shown in FIG. 1, a first valve 1 may be first opened, and the first buffer tank 13 may be connected to a vacuum pump 15. The pressure of the first buffer tank 13 may be reduced to, for example, 1 Pa, or below, by the vacuum pump 15. The process chamber 16 may also be connected to the vacuum pump 15 and may be adjusted to have a pressure suitable for the process, for example, 133 Pa. At this time, in the container 12, a vapor may be generated from a precursor at a saturated vapor pressure, for example, 27 Pa.

Next, as shown in FIG. 2, the first valve 1 may be closed, and a second valve 2, a third valve 3, and a fourth valve 4 between the container 12 and the first buffer tank 13 may be opened, and vapor may be introduced into the first buffer tank 13. At this time, the pressure within the first buffer tank 13 may be the saturated vapor pressure, for example, 27 Pa. In this state, the vapor cannot be introduced into the process chamber in which the process pressure is, for example, 133 Pa. In addition, when there is a second buffer tank 14, a fifth valve 5 may be opened so that the second buffer tank 14 may be connected to the vacuum pump 15. The pressure of the second buffer tank 14 may be reduced to, for example, 1 Pa, or below, by the vacuum pump 15.

Next, as shown in FIG. 3, the fourth valve 4 may be closed and a sixth valve 6 may be opened, so that the first buffer tank 13 may be connected to the gas source 11, for instance an inert gas. The first buffer tank 13 may be pressurized to hundreds of Pa as an inert gas is introduced thereinto from the gas source 11. The first buffer tank 13 is pressurized by the gas source 11, but the cylinder or accumulator provided in the first buffer tank 13 may also be pressurized to hundreds of Pa. In this manner, when the first buffer tank 13 is pressurized and the seventh valve 7 is opened, the first buffer tank 13 may pressure-feed vapor into the process chamber 16. In addition, when a second buffer tank 14 is included, the second valve 2, the third valve 3, and the eighth valve 8 between the second buffer tank 14 and the container 12 may be opened and vapor may be introduced into the second buffer tank 14. At this time, pressure within the second buffer tank 14 may be the saturated vapor pressure, for instance, 27 Pa.

Finally, as shown in FIG. 4, as the sixth valve 6 and the seventh valve 7 are closed and the first valve 1 is opened, the first buffer tank 13 may be connected to the vacuum pump 15 and the pressure of the first buffer tank 13 may be reduced to, for example, 1 Pa, or below. That is, the first buffer tank 13 may return to the state shown in FIG. 1. Accordingly, by performing the processes of FIGS. 1 to 4 again, vapor having the saturated vapor pressure lower than the process pressure of the process chamber 16 may be stably supplied.

In addition, as shown in FIG. 4, when the second buffer tank 14 exists, a ninth valve 9 may be opened so that the second buffer tank 14 may be connected to the gas source 11. The second buffer tank 14 may be pressurized to hundreds of Pa as an inert gas is introduced from the gas source 11. The second buffer tank 14 is pressurized by the gas source 11, but a cylinder or accumulator provided in the second buffer tank 14 may also be pressurized to hundreds of Pa. In addition, as a tenth valve 10 is opened, the second buffer tank 14 may pressure-feed vapor to the process chamber 16. In this manner, since the second buffer tank 14 is used in addition to the first buffer tank 13, vapor may be continuously supplied to the process chamber.

According to the present disclosure, the vapor supply apparatus which may be used for both sublimation and evaporation and is capable of pressurizing the buffer tank may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While example implementations have been shown and described above, it will be apparent to those skilled in the art that modifications and variations could be made without departing from the scope of the present disclosure as defined by the appended claims.

1.-12. (canceled)

13. A vapor supply apparatus comprising:
a process chamber configured to perform a process at a process pressure using a vapor produced from a precursor;
a container configured to contain the precursor and the vapor, wherein a vapor pressure of the precursor is less than the process pressure;
a first buffer tank between the container and the process chamber; and
a first pressure-feeding mechanism configured to pressurize the first buffer tank and to pressure-feed the vapor from the first buffer tank to the process chamber.

14. The vapor apparatus of claim 13, wherein the first pressure-feeding mechanism comprises a cylinder or an accumulator.

15. The vapor apparatus of claim 14, wherein the first pressure-feeding mechanism comprises an inert gas introducing mechanism.

16. The vapor apparatus of claim 13, further comprising:
a first pipe connecting the container to the first buffer tank;
a first heater configured to control a temperature of the first pipe;
a second pipe connecting the first buffer tank to the process chamber;
a second heater configured to control a temperature of the second pipe;
a third heater configured to control a temperature of the container; and
a fourth heater configured to control a temperature of the first buffer tank,
wherein each heater operates independently of the other heaters.

17. The vapor apparatus of claim 13, further comprising:
a container pressure gauge configured to monitor a pressure of the container;
a first buffer tank pressure gauge configured to monitor a pressure of the first buffer tank; and
a controller configured to independently control the container pressure and the first buffer tank pressure based on measurements of the pressure gauges.

18. The vapor apparatus of claim 17, wherein the controller is further configured to control the process pressure.

19. The vapor apparatus of claim 15, wherein the accumulator or the cylinder
(i) compresses, in the first buffer tank, a volume of the vapor by a factor of at least five for pressure-feeding the vapor into the process chamber; or
(ii) pressure-feeds the vapor from the first buffer tank to the process chamber at five or more times a vapor saturation pressure.

20. The vapor apparatus of claim 13, further comprising: a set of valves configured to control gas flow into and out of the container, the first buffer tank, and the process chamber.

21. The vapor apparatus of claim 20, further comprising a pump configured to reduce a pressure in the process chamber to below a base pressure.

22. The vapor apparatus of claim 21, wherein the pump and the set of valves are configured to pump the first buffer tank to the base pressure.

23. The vapor supply apparatus of claim 13, further comprising:
a second buffer tank between the container and the process chamber; and
a second pressure-feeding mechanism configured to pressurize the second buffer tank and to pressure-feed the vapor from the second buffer tank to the process chamber.

24. The vapor apparatus of claim 23, wherein the second pressure-feeding mechanism comprises a cylinder or an accumulator.

25. The vapor apparatus of claim 24, wherein the second pressure-feeding mechanism comprises an inert gas introducing mechanism.

26. The vapor apparatus of claim 13, further comprising:
a second buffer tank between the container and the process chamber; and
a second pressure-feeding mechanism configured to pressurize the second buffer tank and to pressure-feed the vapor from the second buffer tank to the process chamber.
a first pipe connecting the container to the first buffer tank;
a first heater configured to control a temperature of the first pipe;
a second pipe connecting the container to the second buffer tank;
a second heater configured to control a temperature of the second pipe;
a third pipe connecting the first buffer tank to the process chamber;
a third heater configured to control a temperature of the third pipe;
a fourth pipe connecting the second buffer tank to the process chamber;
a fourth heater configured to control a temperature of the fourth pipe;
a fifth heater configured to control a temperature of the container;
a sixth heater configured to control a temperature of the first buffer tank; and
a seventh heater configured to control a temperature of the second buffer tank,
wherein each heater operates independently of the other heaters.

27. The vapor apparatus of claim 13, further comprising:
a container pressure gauge configured to monitor a pressure of the container;
a first buffer tank pressure gauge configured to monitor a pressure of the first buffer tank;
a second buffer tank pressure gauge configured to monitor a pressure of the second buffer tank; and
a controller configured to independently control the container pressure, the first buffer tank pressure, and the second buffer tank pressure based on measurements of the pressure gauges.

28. The vapor apparatus of claim 27, further comprising: a set of valves configured to control gas flow into and out of the container, the first buffer tank, the second buffer tank, and the process chamber.

29. The vapor apparatus of claim 28, further comprising a pump configured to reduce a pressure in the process chamber to below a base pressure.

30. The vapor apparatus of claim 29, wherein the pump and the set of valves are configured to pump the first buffer tank and the second buffer tank to the base pressure.

31. The vapor apparatus of claim 27, wherein the controller, the first buffer tank, the second buffer tank, the set of valves, and the pump are configured to supply the process chamber with the vapor at a selected vapor pressure continuously by alternating pressure feeding the process chamber between the first buffer tank and the second buffer tank.

32. The vapor apparatus of claim 31, further comprising one or more additional buffer tanks.
